(19) United States
(12) Patent Application Publication
(10) Pub. No.: US 2025/0187551 A1
(43) Pub. Date: Jun. 12, 2025

(54) STAMPED BUBBLE SHEET WITH DAMPING ENHANCEMENT

(71) Applicant: GM GLOBAL TECHNOLOGY OPERATIONS LLC, Detroit, MI (US)

(72) Inventors: Song HE, Troy, MI (US); Arianna T. MORALES, Bloomfield Hills, MI (US); Anil K. SACHDEV, Rochester Hills, MI (US); Xuan Q. TRAN, Novi, MI (US)

(21) Appl. No.: 18/536,848

(22) Filed: Dec. 12, 2023

(51) Int. Cl. B60R 13/08; B21D 53/88

(52) U.S. Cl. CPC B60R 13/0815; B21D 53/88

(57) ABSTRACT

A cover panel includes a formed first metal sheet having a plurality of spaced protrusions formed therein. A plurality of sound deadening pads are applied to the formed first metal sheet. A second metal sheet is secured to the formed first metal sheet.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a cover member formed as a formed bubble sheet with damping enhancement.

Many vehicle components and industrial systems give off vibrations that are undesirable to a vehicle's occupants or to an operator of an industrial system. Some systems are housed within a compartment that can be designed to contain and/or inhibit the transmission of undesired vibrations and noises.

### SUMMARY

The present disclosure relates to a cover or panel that includes a formed first sheet having a plurality of spaced protrusions formed therein. A plurality of sound deadening pads are applied to the formed first sheet. A second sheet is secured to the formed first sheet.

According to a further aspect, the plurality of sound deadening pads include a plurality of patches that are adhered to the stamped first metal sheet.

According to a further aspect, the plurality of sound deadening pads are a liquid applied sound deadening material.

According to a further aspect, the plurality of sound deadening pads are each applied between adjacent protrusions.

According to a further aspect, the plurality of sound deadening pads are compressed by the second sheet.

According to a further aspect, the first and second sheets are made from metal and are welded to each other.

According to a further aspect, the second sheet is adhered to the first sheet.

According to a further aspect, the formed first sheet has a perimeter edge that is raised at a same height as the plurality of spaced protrusions.

According to a further aspect, the formed first sheet and the second sheet are made from one of aluminum, magnesium, titanium, polymer composite, carbon fiber composite and steel.

According to a further aspect, the second metal sheet is flat.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a plan view of a formed first sheet panel of a cover assembly according to the principles of the present disclosure;

FIG. 2 is a plan view of a second sheet panel of a cover assembly according to the principles of the present disclosure;

FIG. 3 is a plan view of the formed first sheet panel having damping pads applied to the formed first sheet panel according to the principles of the present disclosure; and

FIG. 4 is a cross-sectional view of the cover assembly according to the principles of the present disclosure.

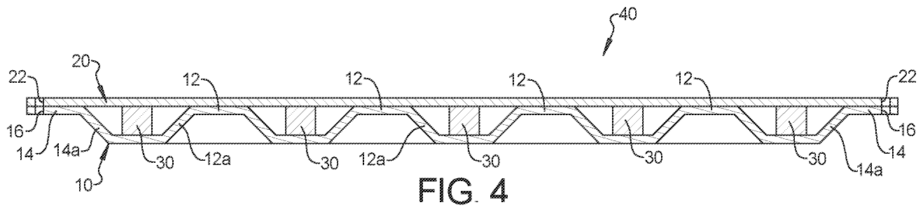

In the drawings, reference numbers may be reused to identify similar and/or identical elements.

### DETAILED DESCRIPTION

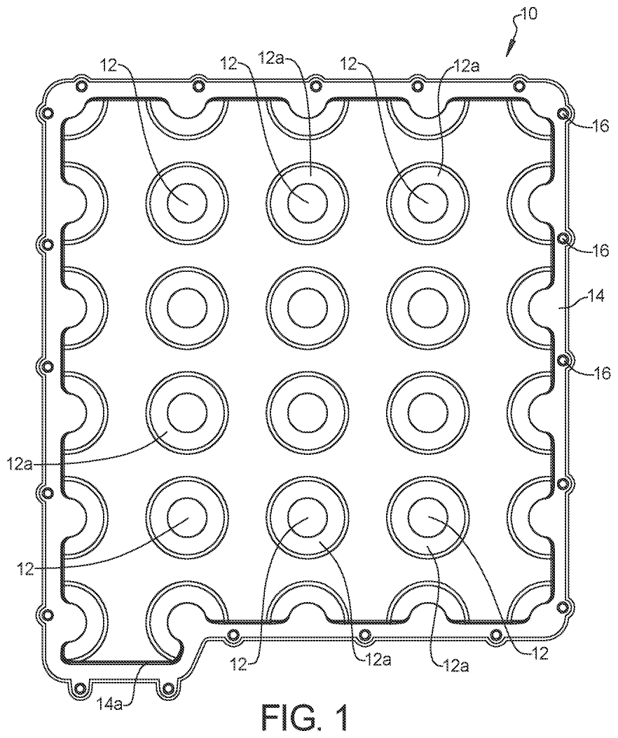

With reference to FIG. 1, a formed first sheet panel 10 of a cover assembly is shown. The formed first sheet panel 10 can be made from aluminum, magnesium, titanium, polymer composite, carbon fiber composite or steel. The stamped first sheet metal panel 10 can be stamped from a flat sheet to include a plurality of protrusions 12. As shown, the protrusions 12 can be round with conical sidewalls 12a, although other shapes including square, oval, rectangular, elongated, letters, logos and other shapes can be used. The protrusions 12 can provide added strength to the formed first sheet panel 10. The protrusions 12 can be formed by stamping or molding. A perimeter edge 14 of the stamped first sheet metal panel 10 can also be raised at a height that is equal to or greater than a height of the dimples 12. The perimeter edge can include a sloped sidewall 14a extending upward from the remainder to the panel. The perimeter edge 14 of the stamped first sheet metal panel 10 can include a plurality of mounting apertures 16 formed therein.

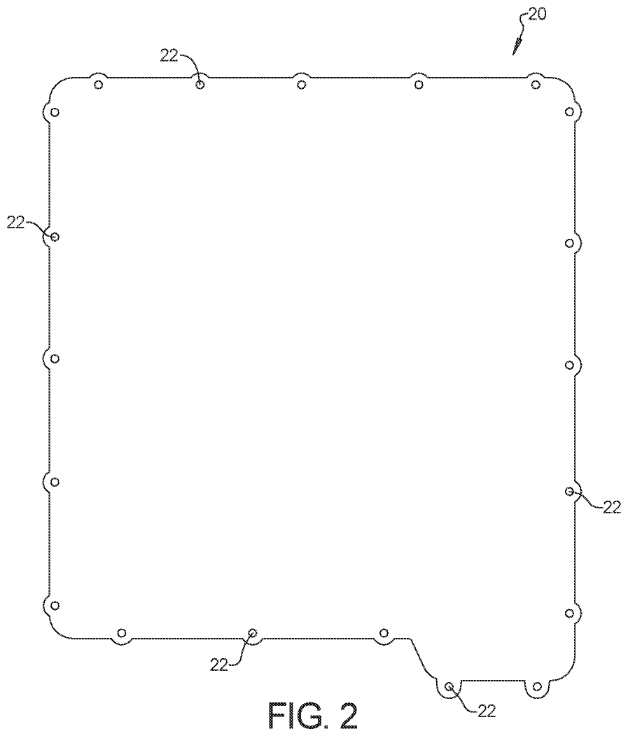

As shown in FIG. 2, a second sheet panel 20 having a same perimeter shape as the perimeter of the formed first sheet panel 10. The second sheet panel 20 can be made from aluminum, magnesium, titanium, polymer composite, carbon fiber composite or steel. Although the second sheet panel 20 is shown as flat, the second sheet panel 20 can also include protrusions formed therein. The protrusions can be round, square, oval, rectangular, letters, logos and other shapes, as desired. The protrusions can provide added strength to the second sheet panel 20. The second sheet panel also includes a plurality of mounting apertures 22 that align with the mounting apertures 16 of the stamped first sheet metal panel 10.

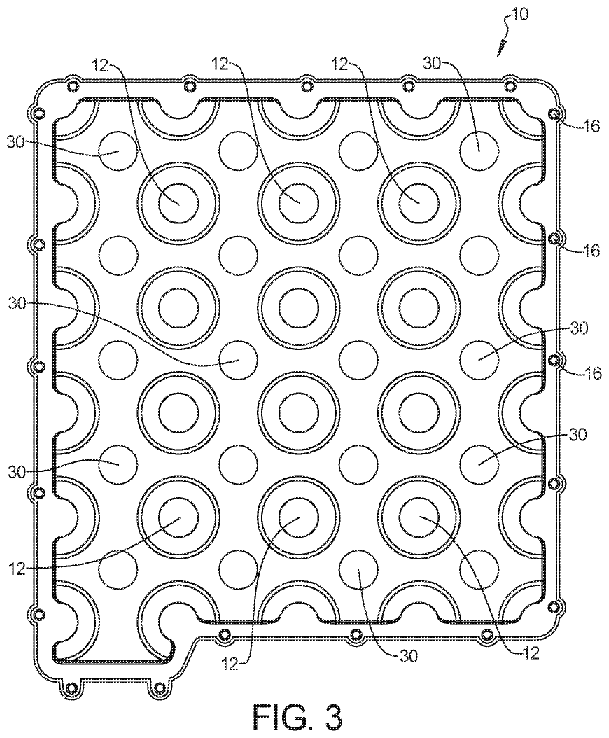

With reference to FIG. 3, the formed first sheet panel 10 is shown including a plurality of damping pads 30 applied to the formed sheet panel 10 between the protrusions 12. The damping pads 30 can be made from metal, silicone, rubber, foam or other material. The damping pads 30 can be adhered to the formed first sheet panel 10 in the pattern as shown, or alternative patterns. The damping pads 30 can also be a liquid applied sound deadening material with the pads being applied as a liquid that solidifies as it dries or cures.

The second sheet panel 20 is secured to the formed first sheet panel 10 around the perimeter edge 14 to form a cover assembly 40. The second sheet metal panel 20 can be laser welded, adhered or otherwise secured to the formed first sheet panel 10. The damping pads 30 can be taller than the raised perimeter edge 14 of the formed first sheet panel 10 and made from a compressible material that can be compressed by the second sheet panel 20. The damping pads 30 can alternatively be shorter than the raised perimeter edge 14 of the formed first sheet panel 10 so that the damping pads 30 do not contact the second sheet panel 20. The material, size, weight and position of the damping pads 30 can be selected to isolate the vibration and noise frequencies known to emanate from the system for which the cover is designed. The damping pads 30 can also be alternatively or additionally applied to the second sheet panel 20.

The cover assembly 40 can be applied to a housing of various vehicle components and industrial machines for isolating vibrations and noises emanated therefrom. The cover assembly 40 provides a lightweight structure with mass reduction due to increased stiffness/strength of pre-formed sheets. The formed protrusion design accommodates damping material application inside the panels. The testing performed with the composite structure shows significantly improved damping and NVH performance and higher stiffness. The formed pattern can be customized to include artistic design to enhance panel appeal. The protrusions 12 strengthen the cover assembly 40 and the damping pads 30 dampen vibration and noise frequencies created by the vehicle component.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A cover panel, comprising:
a formed first sheet having a plurality of spaced protrusions formed therein;
a plurality of sound deadening pads applied to the formed first sheet; and
a second sheet secured to the formed first sheet.

2. The cover panel according to claim 1, wherein the plurality of sound deadening pads include a plurality of patches that are adhered to the formed first sheet.

3. The cover panel according to claim 1, wherein the plurality of sound deadening pads are a liquid applied sound deadening material.

4. The cover panel according to claim 1, wherein the plurality of sound deadening pads are each applied between two adjacent protrusions.

5. The cover panel according to claim 1, wherein the plurality of sound deadening pads are compressed by the second sheet.

6. The cover panel according to claim 1, wherein the first and second sheets are made from metal and are welded together.

7. The cover panel according to claim 1, wherein the second sheet is adhered to the formed first sheet.

8. The cover panel according to claim 1, wherein the formed first sheet has a perimeter edge that is raised at a same height as the plurality of spaced protrusions.

9. The cover panel according to claim 1, wherein the formed first sheet and the second sheet are made from one of aluminum, magnesium, titanium, polymer composite, carbon fiber composite and steel.

10. The cover panel according to claim 1, wherein the second sheet is flat.

11. A method of making a cover panel, comprising:
stamping a first flat sheet metal panel to include a plurality of spaced protrusions and a raised peripheral surface formed therein;
forming a second sheet metal panel;
applying a plurality of sound deadening pads to one of the stamped first sheet metal panel and the second sheet metal panel; and
securing the second sheet metal panel to the stamped first sheet metal panel.

12. The method according to claim 11, wherein the plurality of sound deadening pads include a plurality of patches that are adhered to the stamped first sheet metal panel.

13. The method according to claim 11, wherein the plurality of sound deadening pads are a liquid applied sound deadening material.

14. The method according to claim 11, wherein the plurality of sound deadening pads are each applied between adjacent protrusions.

15. The method according to claim 11, wherein the plurality of sound deadening pads are compressed by the second sheet metal panel.

16. The method according to claim 11, wherein the second sheet metal panel is welded to the stamped first sheet metal panel.

17. The method according to claim 11, wherein the second sheet metal panel is adhered to the stamped first sheet metal panel.

18. The method according to claim 11, wherein the peripheral surface of the stamped first sheet metal panel is raised at a same height as the plurality of spaced protrusions.

19. The method according to claim 11, wherein the stamped first sheet metal panel and the second sheet metal panel are made from one of aluminum, magnesium, titanium and steel.

20. The method according to claim 11, wherein the second sheet metal panel is flat and is secured to the raised peripheral surface of the first stamped sheet metal panel.
